(19) United States
(12) Patent Application Publication
(10) Pub. No.: US 2026/0096166 A1
(43) Pub. Date: Apr. 2, 2026

(54) POWER SEMICONDUCTOR DEVICE AND METHOD OF PRODUCING A POWER SEMICONDUCTOR DEVICE

(71) Applicant: Infineon Technologies AG, Neubiberg (DE)

(72) Inventors: Thorsten Arnold, Jesenwang (DE); Maziar Noei, Aachen (DE); Benedikt Stoib, Feldkirchen-Westerham (DE); Jakob Wierzbowski, Neubiberg (DE); Christina Elena Witt, Pegnitz (DE); Oana Iulia Spulber, Neubiberg (DE); Andreas Naumann, Langerbrück (DE); Christian Philipp Sandow, Haar (DE); Dominik Heiß, Dresden (DE)

(21) Appl. No.: 19/328,735

(22) Filed: Sep. 15, 2025

(30) Foreign Application Priority Data
Sep. 27, 2024 (DE) 102024209445.5
Dec. 18, 2024 (DE) 102024138483.2

(51) Int. Cl. H10D 62/60; H10D 12/00; H10D 12/01; H10D 62/10; H10D 84/00

(52) U.S. Cl. CPC H10D 62/60; H10D 12/038; H10D 12/481; H10D 62/126; H10D 84/161

(57) ABSTRACT

A power semiconductor device includes a back side emitter region laterally segmented into at least first and second emitter regions. The first emitter region has a first lateral total area (A1) and, with respect to the first lateral total area and a second conductivity type, a medium dopant dose (D_M). The second emitter region has a second lateral total area (A2) and includes one or more first subregions and one or more second subregions, where A1<0.5*A2. The first subregion(s) form/forms a first portion of the second lateral total area and has/have, with respect to the first portion and the second conductivity type, a high dopant dose (D_H). The second subregion(s) form/forms a second portion of the second lateral total area and has/have, with respect to the second portion and the second conductivity type, a low dopant dose (D_L), where D_H>1.5*D_M and D_L<0.5*D_M.

### TECHNICAL FIELD

This specification refers to embodiments of a power semiconductor device and to embodiments of a method of producing a power semiconductor device.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device comprises a semiconductor body configured to conduct a forward load current along a load current path between two load terminals of the device. The load current is conducted by means of an active region of the power semiconductor device. The active region is surrounded by an edge termination region, which is terminated by an edge of the chip.

In case of a controllable power semiconductor device, e.g., a transistor, the load current path may be controlled by means of insulated electrodes, commonly referred to as gate electrodes. For example, upon receiving a corresponding control signal, e.g., from a driver unit and via a control terminal of the device, the control electrodes may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Conducting) IGBT is one representative of such devices. In an RC IGBT, a single chip unites an IGBT structure and a diode structure.

It is often a design goal to provide the power semiconductor device with specific characteristics, for example relating to the switching properties, e.g., the associated control of the rate of change of the load current (dI/dt) and/or of the rate of change of the collector/emitter voltage (dV/dt).

For example, Green Power Device, GPD, applications typically require a small dV/dt at low current densities like 10% or even 1% of the nominal current density, e.g., to prevent damage to the motor windings. In this area, where silicon solutions dominate still due to the low switching frequency, it is a challenge to reduce turn-on losses and the dV/dt at the same time due to the strong increase of the turn-on dV/dt at smaller current densities.

An additional challenge is the diode over-voltage, which may, inter alia, limit a required gate resistance. In some cases, the softness of the diode cannot be improved sufficiently, and a large diode over-voltage may occur after the removal of the stored charge in the diode, e.g., when switching at low current densities. In these cases, a smaller dV/dt of the IGBT at low current densities supports reducing the reverse recovery current of the diode and reduces the diode over-voltage, additionally. In other cases, a smaller turn-on dV/dt at small current densities and reduced diode over-voltage supports switching at a smaller gate resistance, thus reducing switching losses. In still other cases, the softness requirements of the diode and its stored charge can be reduced by a smaller turn-on dV/dt of the IGBT at small current densities, thus enabling smaller reverse recovery and IGBT turn-on losses.

In short words, a smaller increase of the turn-on dV/dt with decreasing current density without degrading the on-state performance is a challenge, e.g., to satisfy GPD requirements, improve diode softness and enable a further shrink of future IGBTs for a broad range of applications.

### SUMMARY

According to an embodiment, a power semiconductor device comprises a control terminal and an active region with: a semiconductor body comprising a drift region of a first conductivity type and exhibiting a front side and a back side opposite thereof; a first load terminal at the front side; a second load terminal at the back side; in the semiconductor body, a source region of the first conductivity type and a body region of a second conductivity type between the source region and the drift region, wherein both the source region and the body region are electrically connected to the first load terminal; in the semiconductor body, a back side emitter region of the second conductivity type electrically connected to the second load terminal between the drift region and the back side, wherein the back side emitter region is laterally segmented into at least a first emitter region and a second emitter region. The first emitter region has a first lateral total area and exhibits, with respect to said first lateral total area and the second conductivity type, a medium dopant dose. The second emitter region has a second lateral total area and comprises one or more first subregions and one or more second subregions, the first lateral total area amounting to less than 50% of the second lateral total area. The first subregions form a first portion of the second lateral total area and exhibit, with respect to said first portion and the second conductivity type, a high dopant dose, and the second subregions form a second portion of the second lateral total area and exhibit, with respect to said second portion and the second conductivity type, a low dopant dose. The high dopant dose amounts to more than 150% of the medium dopant dose, and the low dopant dose amounts to less than 50% of the medium dopant dose.

According to a further embodiment, a power semiconductor device has a vertical IGBT configuration or a vertical RC IGBT configuration, and the power semiconductor device comprises, in an active region, a back side emitter region laterally segmented into at least a first emitter region and a second emitter region. The first emitter region has a first lateral total area and exhibits, with respect to said first lateral total area and the second conductivity type, a medium dopant dose. The second emitter region has a second lateral total area and comprises one or more first subregions and one or more second subregions, the first lateral total area amounting to less than 50% of the second lateral total area. The first subregions form a first portion of the second lateral total area and exhibit, with respect to said first portion and the second conductivity type, a high dopant dose, and the second subregions form a second portion of the second lateral total area and exhibit, with respect to said second portion and the second conductivity type, a low dopant dose. The high dopant dose amounts to more than 150% of the medium dopant dose, and the low dopant dose amounts to less than 50% of the medium dopant dose.

According to another embodiment, a method of producing a power semiconductor device comprises forming, in an active region, the following components: a semiconductor body comprising a drift region of a first conductivity type and exhibiting a front side and a back side opposite thereof; a first load terminal at the front side; a second load terminal at the back side; in the semiconductor body, a source region of the first conductivity type and a body region of a second conductivity type between the source region and the drift region, wherein both the source region and the body region are electrically connected to the first load terminal; in the semiconductor body, a back side emitter region of the second conductivity type electrically connected to the second load terminal between the drift region and the back side, wherein the back side emitter region is laterally segmented into at least a first emitter region and a second emitter region. The first emitter region has a first lateral total area and exhibits, with respect to said first lateral total area and the second conductivity type, a medium dopant dose. The second emitter region has a second lateral total area and comprises one or more first subregions and one or more second subregions, the first lateral total area amounting to less than 50% of the second lateral total area. The first subregions form a first portion of the second lateral total area and exhibit, with respect to said first portion and the second conductivity type, a high dopant dose, and the second subregions form a second portion of the second lateral total area and exhibit, with respect to said second portion and the second conductivity type, a low dopant dose. The high dopant dose amounts to more than 150% of the medium dopant dose, and the low dopant dose amounts to less than 50% of the medium dopant dose.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a horizontal projection of a power semiconductor device in accordance with one or more embodiments;

FIG. 2 schematically and exemplarily illustrates a vertical cross-section of a section of a power semiconductor device in accordance with one or more embodiments;

FIG. 3 schematically and exemplarily illustrates a vertical cross-section of a section of a power semiconductor device in accordance with one or more embodiments;

FIG. 4A schematically and exemplarily illustrates a horizontal projection of a section of a back side emitter region of a power semiconductor device in accordance with one or more embodiments;

FIG. 4B schematically and exemplarily illustrates a vertical cross-section of a section of a power semiconductor device in accordance with one or more embodiments and corresponding with FIG. 4A; and

FIGS. 5 to 15 each schematically and exemplarily illustrates a horizontal projection of a back side emitter region of a section of a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor device described below may be a single semiconductor chip, e.g., exhibiting a stripe cell configuration (or a needle cell configuration) and can be configured to be employed as a power component in a low-, medium- and/or high voltage application, e.g., in a GPD application as mentioned in the introduction.

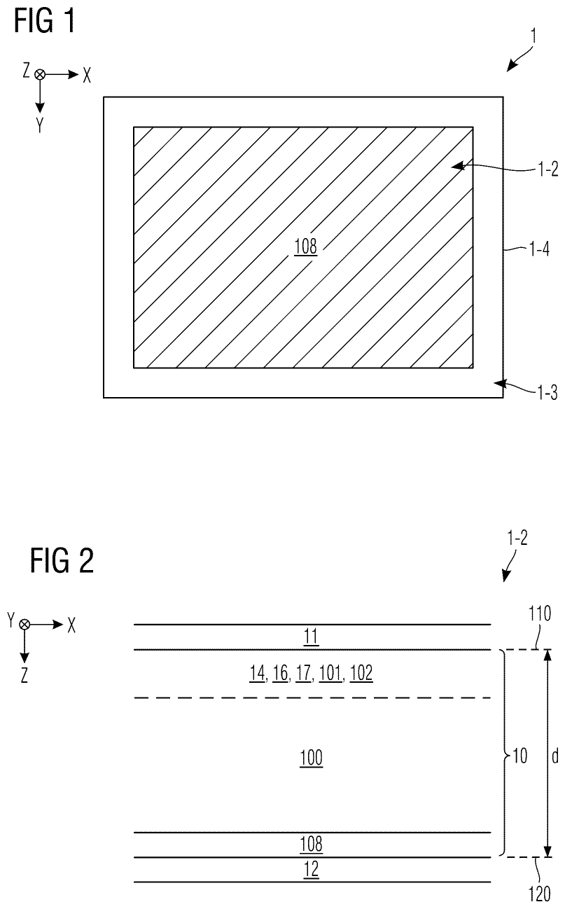

With respect to FIGS. 1 to 3, aspects related to a possible general configuration of the power semiconductor device 1 shall be explained:

The power semiconductor device 1, herein also referred to as “device 1”, comprises, e.g., in a single chip, a semiconductor body 10 configured to conduct a load current, in an active region 1-2, between a first load terminal 11 at a first side 110 (also referred to as front side 110) of the semiconductor body 10 and a second load terminal 12 at a second side 120 (also referred to as back side 120) of the semiconductor body 10. The device 1 can be an IGBT (or a derivative thereof, such as RC IGBT). Accordingly, the first load terminal 11 may be an emitter terminal, and the second load terminal 12 may be a collector terminal.

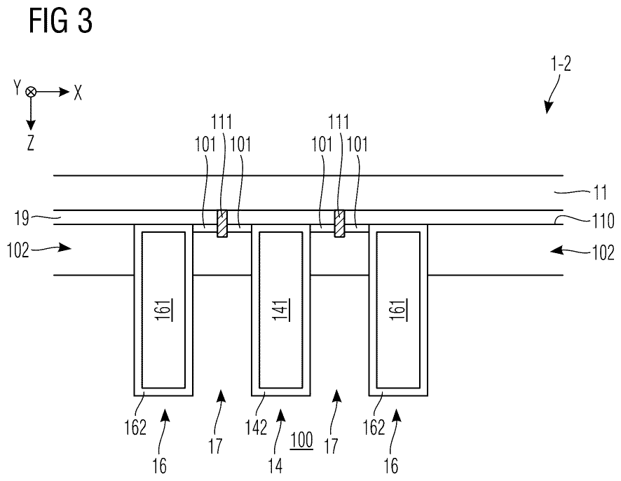

As exemplarily illustrated in FIG. 1, the active region 1-2 of the device 1 is surrounded by an edge termination region 1-3. In the active region 1-2, a trench structure (cf. FIG. 3, reference numerals 14, 16) may form a cell field, which will be explained further below. The edge termination region 1-3 is typically not employed for load current conduction, as it is known to the skilled person. The edge termination region 1-3 is terminated by the chip edge 1-4.

As exemplarily illustrated in FIG. 2, the first side 110 and the second side 120 may be arranged opposite of each other. For example, the first side 110 is a front side of the device 1 and the second side 120 is a back side of the device 1. Accordingly, the device 1 may exhibit a vertical configuration according to which the load current within the device 1 follows a path in parallel to the vertical direction Z.

The semiconductor body 10 may be sandwiched between the first load terminal 11 and the second load terminal 12 and exhibit a vertical extension d, e.g., in the range of 50 μm to 700 μm, depending, e.g., on the designated maximal blocking voltage.

The device 1 further comprises a drift region 100 of a first conductivity type within the semiconductor body 10. Herein, the term “drift region” is employed with the meaning the skilled person typically associates therewith in the field of power semiconductor devices. For example, the vertical extension of the drift region 100 influences the voltage blocking capabilities (e.g., said maximal blocking voltage) of the device 1.

The device 1 further comprises a trench structure 14, 16 that extends from the front side 110 into the semiconductor body 10 towards the back side 120, e.g., along the vertical direction Z.

For example, the trench structure extends into the active region 1-2 and comprises a plurality of control trenches 14, each control trench 14 including a control trench electrode 141 configured to control the forward load current. Each of the control trenches 14 includes a control trench insulator 142 that isolates the control trench electrode 141 from the semiconductor body 10, as schematically illustrated in FIG. 3.

The trench structure may further comprise a plurality of source trenches 16, each source trench 16 including a source trench electrode 161 electrically connected to the first load terminal 11. Also, each of the source trenches 16 includes a source trench insulator 162 that isolates the source trench electrode 161 from the semiconductor body 10.

The control trenches 14 and the source trenches 16 may laterally confine mesas 17. For example, each mesa 17 is laterally confined by at least one of the control trenches 14. For example, each mesa 17 or some of the mesas 17 are laterally confined by two of the control trenches 14. Each mesa can comprise one or more semiconductor source regions 101 of the first conductivity type, which is/are electrically connected to the first load terminal 11. Each mesa 17 can comprise a portion of a semiconductor body region 102 of the second conductivity type, wherein the semiconductor body region 102 isolates the one or more semiconductor source regions 101 from a portion of a region of the first conductivity type, e.g., a portion of the drift region 100 within the mesa 17. The semiconductor body region 102 is electrically connected to the first load terminal 11. For example, some of the mesas 17 may not comprise a contact to the first load terminal 11.

The mesas 17 are electrically connected to the first load terminal 11, e.g., as illustrated in FIGS. 3, e.g., based on contact plugs 111 that penetrate an insulation layer 19 between the semiconductor body 10 and the first load terminal 11 to establish contact with both the respective semiconductor source region 101 and the respective semiconductor body region 102 within the mesa 17.

Based on the source trenches 16 and the control trenches 14, a cell field is established in the active region 1-2. Various trench-mesa-patterns may be established. For example, the mesas 17 may either be neighbored by two of the control trenches 14, or by only one of the control trenches 14 and one of the source trenches 16, or by two of the source trenches 16. The trench-mesa-pattern illustrated in FIG. 3 is hence only exemplary. For example, in other embodiments, only control trenches 14 (and no source trenches 16) are provided. In yet other embodiments, further trench types and/or further mesa types are provided. Also, the present disclosure is not limited to trench structures. In other embodiments, lateral control electrodes may be provided.

The control trench electrodes 141 of the trench structure can be configured to induce, upon being subject with a corresponding ON-control signal, an inversion channel in the semiconductor body region 102. This process may set the device 1 into the forward conducting state. The control trench electrode 141 can further be configured to cut off, upon being subject with a corresponding OFF-control signal, said inversion channel in the semiconductor body region 102, which can set the device 1 into the forward blocking state.

A back side emitter region 108 of the semiconductor body 10 below the drift region 100 and adjoining the second load terminal 12 at the back side 120 can be configured in accordance with the designated characteristic of the device 1. For example, the back side emitter region 108 can be an emitter region of the second conductivity type, if the device 1 shall exhibit an IGBT configuration. The back side emitter region can be arranged in contact with the second load terminal 12.

In addition, a field stop region (not illustrated) of the first conductivity type can be provided between the drift region 100 and back side emitter region 108, wherein the field stop region exhibits a greater dopant concentration than the drift region 100.

In addition, a second barrier region (not illustrated) of the second conductivity type can be provided between the drift region 100 and the trench structure 14, 16. Alternatively or additionally, a first barrier region (not illustrated) of the first conductivity type can be provided between the drift region 100 and the trench structure 14, 16 or between the trench structure 14, 16 and the second barrier region.

If the device 1 shall exhibit an RC IGBT configuration, the back side emitter region 108 may exhibit subsections of the first conductivity type, as it is known to the skilled person.

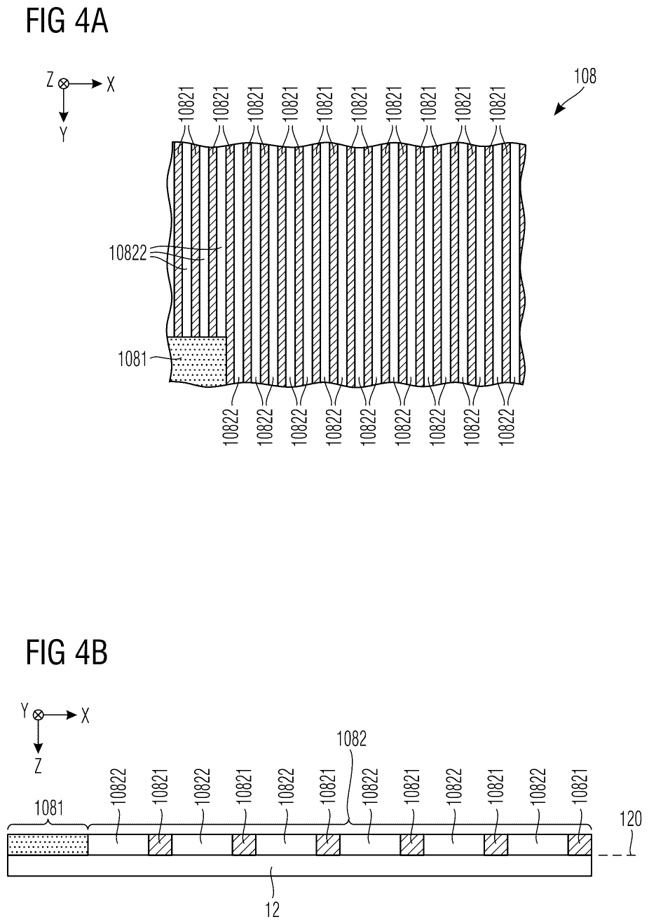

FIGS. 4A and 4B schematically illustrate an exemplary configuration of the back side emitter region 108 within the active region 1-2 in accordance with one or more embodiments. For example, the embodiment of the device 1 exhibiting one or more features of such exemplary configuration of the back side emitter region 108 has a control terminal 13, e.g., electrically connected to the control trench electrodes 141 and, within the active region 1-2, said semiconductor body 10 comprising said drift region 100 of the first conductivity type and exhibiting said front side 110 and said back side 120 opposite thereof; said first load terminal 11 at the front side 110; said second load terminal 12 at the back side 120; and, in the semiconductor body 10, said source region 101 of the first conductivity type and said body region 102 of the second conductivity type between the source region 101 and the drift region 100, wherein both the source region 101 and the body region 102 are electrically connected to the first load terminal 11. Further, the back side emitter region 108 of the second conductivity type is electrically connected to the second load terminal 12 and arranged between the drift region 100 and the back side 120. Further, the embodiment of the device 1 exhibiting the one or more features of the exemplary configuration of the back side emitter region 108 schematically illustrated in FIGS. 4A and 4B may exhibit one or more features of the embodiments described with respect to FIGS. 1 to 3.

In accordance with the embodiment illustrated in FIGS. 4A-4B, the device 1 may exhibit an IGBT configuration or an RC IGBT configuration, e.g., a vertical IGBT configuration or a vertical RC IGBT configuration.

As illustrated in FIGS. 4A and 4B, the back side emitter region 108 may be laterally segmented into at least a first emitter region 1081 and a second emitter region 1082. For example, the first emitter region 1081 and the second emitter region 1082 may exhibit the same thickness or at least a substantially identical thickness along the vertical direction Z. Further, the first emitter region 1081 and the second emitter region 1082 may arranged at the same vertical level, i.e., forming an entire overlap along the vertical direction Z.

In accordance with the embodiment illustrated in FIGS. 4A-4B, the first emitter region 1081 has a first lateral total area (in parallel to the first and second lateral directions X and Y) and exhibits, with respect to said first lateral total area and the second conductivity type, a medium dopant dose.

Further, the second emitter region 1082 has a second lateral total area (also in parallel to the first and second lateral directions X and Y) and comprises one or more first subregions 10821 and one or more second subregions 10822, the first lateral total area amounting to less than 50% of the second lateral total area.

Further, the first subregions 10821 form a first portion of the second lateral total area and exhibit, with respect to said first portion and the second conductivity type, a high dopant dose, and the second subregions 10822 form a second portion of the second lateral total area and exhibit, with respect to said second portion and the second conductivity type, a low dopant dose. The high dopant dose amounts to more than 150% of the medium dopant dose, and the low dopant dose amounts to less than 50% of the medium dopant dose.

In an embodiment, the first subregions 10821 and the second subregions 10822 may exhibit the same thickness or at least a substantially identical thickness along the vertical direction Z. Further, the first subregions 10821 and the second subregions 10822 may be arranged at the same vertical level, i.e., forming an entire overlap along the vertical direction Z.

For example, in accordance with the embodiment illustrated in FIGS. 4A-4B, the device 1 has a structured back side emitter region 108 with a smaller part of it (the first emitter region 1081) containing a blanket p-emitter of intermediate dose, and a larger part (the second emitter region 1082) containing an ESI type of p-emitter. For example, at low current densities, the current is mainly constrained to the smaller part (the first emitter region 1081). For example, the current density in the smaller part is effectively larger and the turn-on Miller plateau at a larger level, which means that the control electrode current is smaller and hence also the turn-on dV/dt. At nominal current densities and beyond, also the larger part (the second emitter region 1082) is conducting and an almost uniform current density distribution is possible.

FIG. 4A illustrates the horizontal cross-section of the back side emitter region 108 almost completely; i.e., the illustrated structure of the back side emitter region 108 may extend within the entire the active region 1-2, as illustrated in FIG. 1, and even, in contrast to the illustration of FIG. 1, partially or entirely within the edge termination region 1-3. Accordingly, in an embodiment, the first emitter region 1081 may be positioned in a peripheral portion of the active region 1-2, i.e., in a corner portion thereof.

In accordance with an embodiment, the first emitter region 1081 is positioned such that a lateral distance between the control terminal 13 and the first emitter region 1081 is smaller compared to a second distance between the control terminal 13 and the second emitter region 1082. For example, the share of the source regions 101 and the body region 102 laterally overlapping with the first emitter region 1081 may be exposed slightly earlier to a change of the control voltage (dV/dt) applied between the control terminal 13 and the first load terminal 11 as compared to the share of the source regions 101 and the body region 102 laterally overlapping with the second emitter region 1082.

In accordance with an embodiment, the first portion of the second lateral total area amounts to 50% to 150% of the second portion of the second lateral total area. Depending on the application, the second lateral total area may be substantially evenly segmented into the first portion and the second portion, i.e., such that first portion of the second lateral total area amounts to 100% of the second portion of the second lateral total area. Other proportions are possible, in accordance with further embodiments.

Still referring to FIGS. 4A and 4B, the second emitter region 1082 exhibits, based on the first subregions 10821 and the second subregions 10822, a stripe configuration, in accordance with one or more embodiments. The first subregions (stripes) 10821 and the second subregions (stripes) 10822 may be configured as illustrated in FIGS. 4A and 4B, i.e., arranged in parallel to each other, but are not limited to such configuration, as will become apparent from the description of the further embodiments.

For example, in an embodiment, both the first subregions 10821 and the second subregions 10822 exhibit a stripe configuration of multiple spatially distributed stripes, wherein a lateral width of the stripes of the first subregions 10821 is substantially identical to a lateral width of the stripes of the second subregions 10822. By contrast, in accordance with the embodiment of FIG. 4B, the widths of the second subregions (stripes) 10822 may in other embodiments be greater than the widths of the first subregions (stripes) 10821. For example, the widths of the second subregions (stripes) 10822 and the widths of the first subregions (stripes) 10821 may in yet further embodiments vary within a range of 50% to 150% of a nominal stripe width.

In accordance with an embodiment, the first subregions 1081 and the second subregions 1082 are substantially evenly distributed within the second emitter region 108. In other embodiments, an uneven distribution of the first subregions 1081 and the second subregions 1082 may be provided.

In accordance with an embodiment, the first emitter region 1081 exhibits a contiguous configuration. Also, the second emitter region 1082 may exhibit a contiguous configuration.

In accordance with an embodiment, wherein the first emitter region 1081 has a lateral shape according to which a maximal total extension along a first lateral direction X is within the range of 33% to 300% of a maximal total extension along any other lateral direction Y. For example, the first emitter region 1081 is configured with a compact lateral shape.

As further illustrated in FIG. 4A, at least one of the one or more first subregions 10821 may adjoin the first emitter region 1081, in accordance with an embodiment. For example, said at least one of the one or more first subregions 10821 adjoining the first emitter region 1081 has a lateral overlap with the first emitter region 1081 of at least 1 μm or of at least 5 μm (cf. also FIG. 12). In the embodiment of FIG. 4A, said lateral overlap is formed, along the first lateral direction X, for each of the three left most first subregions (stripes) 10821.

In accordance with a yet further embodiment, a first share of the source regions 101 and of the body region 102 laterally overlaps with the first emitter region 1081, and a second share of the source regions 101 and the body region 102 laterally overlaps with the second emitter region 1082. For example, both the first emitter region 1081 and the second emitter region 1082 (and its subregions 10821, 10822 and (if present) 10823) form a respective part of the load current path of the device 1, at least at nominal load current.

In accordance with an embodiment, portions of the source region 101 and the body region 102 laterally overlapping with the first emitter region 1081 and the second emitter region 1082 are created equal. For example, the first emitter region 1081 and the second emitter region 1082 have equally formed transistor cells at the front side 110 and are different mostly or only in the configuration of their second emitter region 108.

For example, said first share and said second share are controlled based on the same voltage applied between the first control terminal 11 and the control terminal 13 (which may be connected to the control trench electrodes 141). Furthermore, said first share exhibits a first channel width, and said second share exhibits a second channel width, wherein the second channel width may be different from the first channel width (for example, larger than the first channel width). In addition or in alternative thereto, in said first share, the body region 102 exhibits a first body dopant dose, and, in said second share, exhibits a second body dopant dose different from the first body dopant dose. In another embodiment, said first share and said second share are substantially equally configured.

FIGS. 5 to 15 schematically illustrate further aspects of exemplary configurations of the back side emitter region 108 within the active region 1-2 in accordance with some embodiments. For example, each of the embodiments of the device 1 exhibiting one or more features of the exemplary configurations of the back side emitter region 108 as illustrated in FIGS. 5 to 15 has said control terminal 13 and, within the active region 1-2, said semiconductor body 10 comprising said drift region 100 of the first conductivity type and exhibiting said front side 110 and said back side 120 opposite thereof; said first load terminal 11 at the front side 110; said second load terminal 12 at the back side 120; and, in the semiconductor body 10, said source region 101 of the first conductivity type and said body region 102 of the second conductivity type between the source region 101 and the drift region 100, wherein both the source region 101 and the body region 102 are electrically connected to the first load terminal 11. Further, the back side emitter region 108 of the second conductivity type is electrically connected to the second load terminal 12 and arranged between the drift region 100 and the back side 120. Further, each of the embodiments of the device 1 exhibiting one or more features of the exemplary configuration of the back side emitter region 108 schematically illustrated in FIGS. 5 to 15 may exhibit one or more features of the embodiments described with respect to FIGS. 1 to 4B.

In accordance with the embodiments illustrated in FIGS. 5 to 15, the first emitter region 1081 has a first lateral total area and exhibits, with respect to said first lateral total area and the second conductivity type, a medium dopant dose. Further, the second emitter region 1082 has a second lateral total area and comprises one or more first subregions 10821 and one or more second subregions 10822, the first lateral total area amounting to less than 50% of the second lateral total area. Further, the first subregions 10821 form a first portion of the second lateral total area and exhibit, with respect to said first portion and the second conductivity type, a high dopant dose, and the second subregions 10822 form a second portion of the second lateral total area and exhibit, with respect to said second portion and the second conductivity type, a low dopant dose. The high dopant dose amounts to more than 150% of the medium dopant dose, and the low dopant dose amounts to less than 50% of the medium dopant dose.

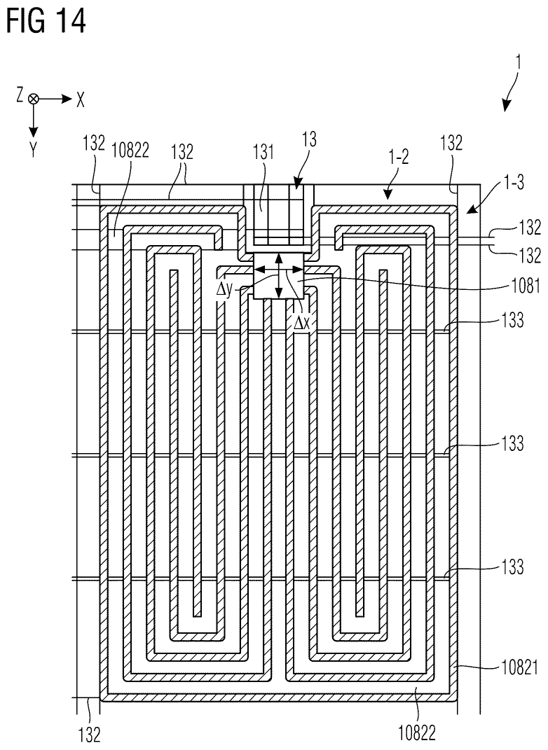

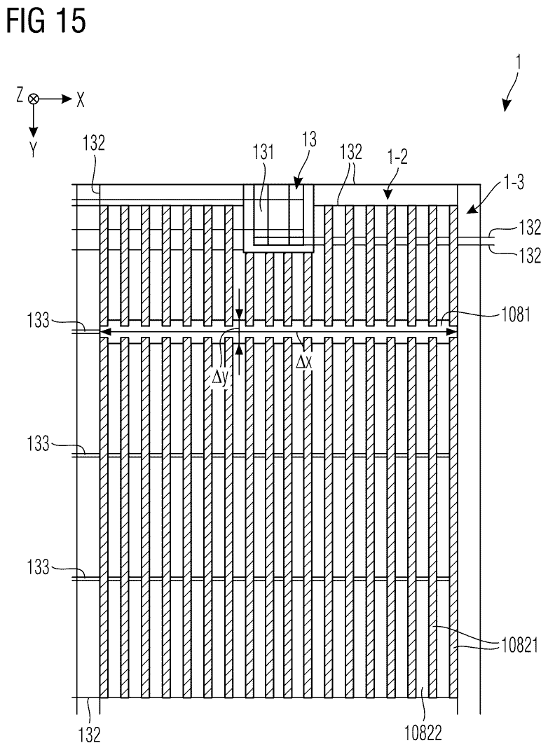

In accordance with the embodiment schematically and exemplarily illustrated in FIG. 5, each of first subregions 10821 adjoins the first emitter region 1081. In this embodiment, the first emitter region 1081 itself exhibits a stripe configuration, e.g., positioned in said peripheral portion of the active region 1-2, e.g., in vicinity to a gate runner or a gate finger (cf. FIGS. 14 and 15, reference numerals 132, 133) electrically connected to the control terminal 13 or a contact pad 131 thereof.

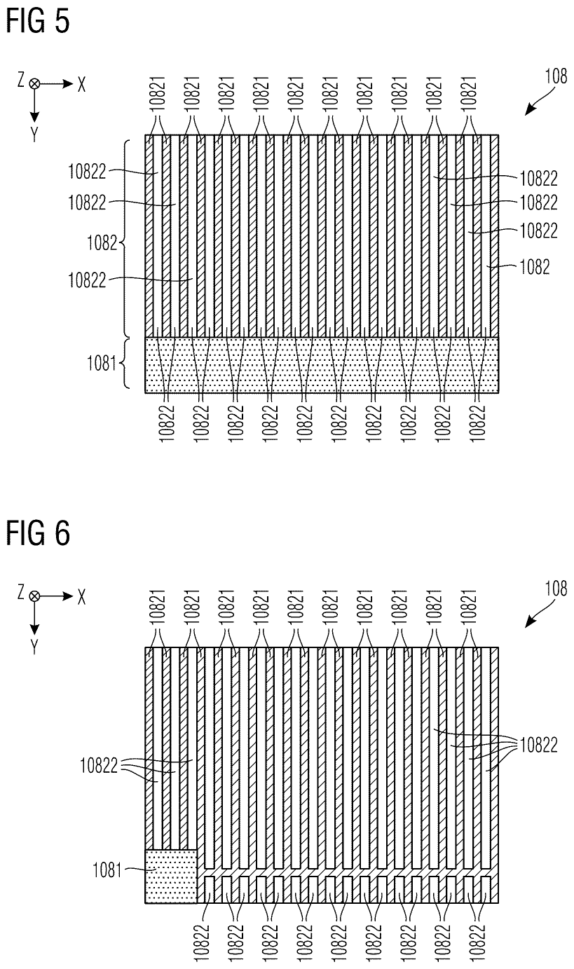

Also in accordance with the embodiment schematically and exemplarily illustrated in FIG. 6, each of first subregions 10821 adjoins the first emitter region 1081. In this embodiment, the first emitter region 1081 has a comparatively compact shape, as in the embodiment of FIGS. 4A and 4B. Each of first subregions 10821 adjoins the first emitter region 1081 also based on one of the first subregions 10821 being implemented as a cross-stripe extending (e.g., in pitch direction) and crossing through remaining first subregions (stripes) 10821 extending perpendicular thereto and not directly adjoining the first emitter region 1081, as illustrated in FIG. 6.

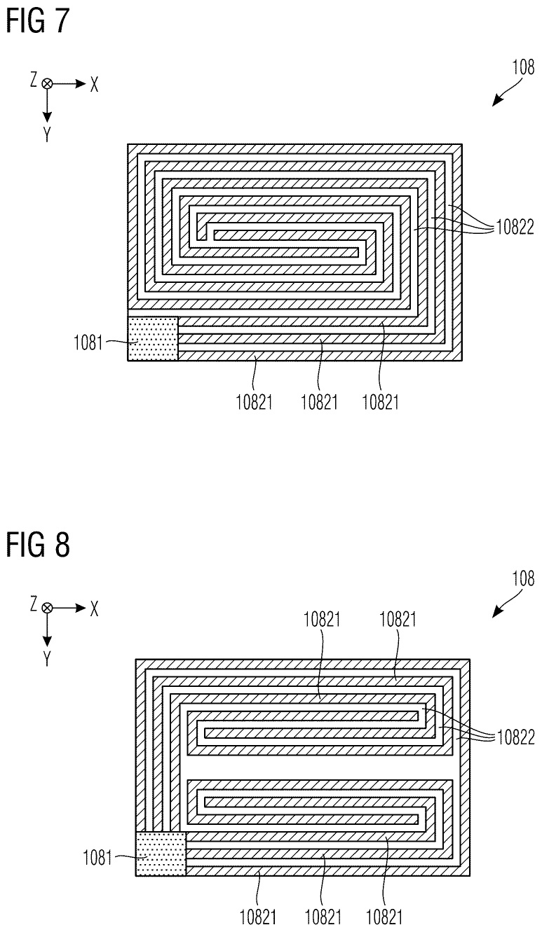

In accordance with the embodiment schematically and exemplarily illustrated in FIG. 7, the second emitter region 1082 exhibits, based on the first subregions 10821 and the second subregions 10822, a meander configuration, e.g., still based on stripes, now extending along a respective meander course through the active region 1-2. A meander configuration may be beneficial in terms of avoiding filamentation. The first emitter region 1081 may still be arranged in vicinity to the control terminal 13 to enable a fast turn-on. In addition, the width of the first subregions (stripes) 10821 adjoining the first emitter region may increase in vicinity to the first emitter region 1081, e.g., by 50% or 100% or more compared to a portion of the first subregions (stripes) 10821 not in vicinity to the first emitter region 1081.

The embodiment schematically and exemplarily illustrated in FIG. 8 is similar to the embodiment schematically and exemplarily illustrated in FIG. 7, wherein the intersection regions between the first subregions (stripes) 10821 and the first emitter region 1081 is increased. Also in accordance with embodiment schematically and exemplarily illustrated in FIG. 8, one of the first subregions (stripes) 10821 surrounds the active region 1-2. For example, the edge termination region 1-3 might be critical with respect to reverse blocking (e.g., due to presence of a d-well), and hence, a p+ stripe at the transition to the edge termination region 1-3 or even at the chip edge 1-4 may be beneficial. In other words, in an embodiment, the back side emitter region 108 may extend into the edge termination region 1-3, e.g., based on the first subregions 10821 and even until the chip edge 1-4, in accordance with an embodiment. A wider first subregion (e.g. stripe) 10821 may be provided at the edge 1-4 due to the smaller current density at the edge, in accordance with an embodiment.

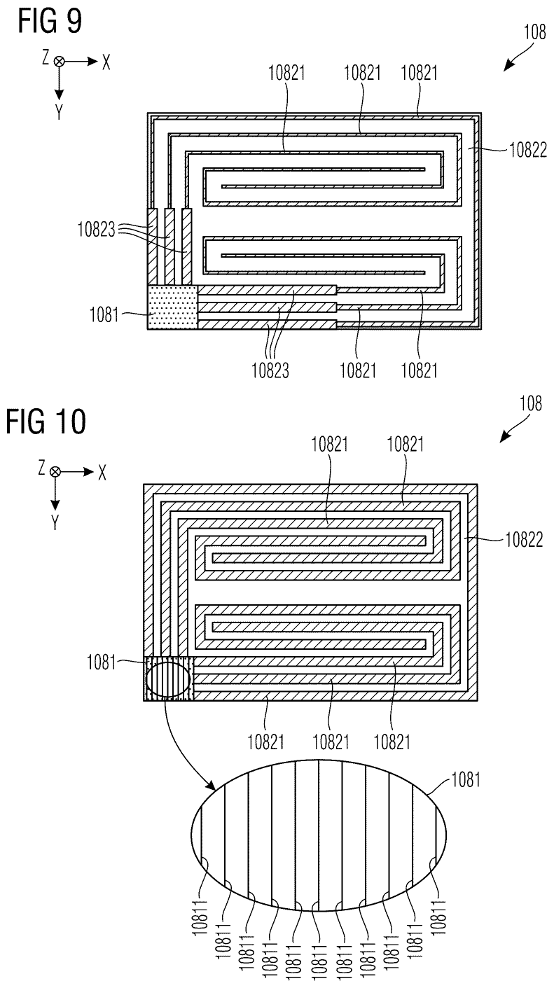

In accordance with the embodiment schematically and exemplarily illustrated in FIG. 9, which can be considered as a variation of the embodiment schematically and exemplarily illustrated in FIG. 8, the second emitter region 1082 comprises one or more third subregions 10823 forming a third portion of the second lateral total area and exhibit, with respect to said third portion and the second conductivity type, a medium-to-high dopant dose, wherein, e.g., the medium-to-high dopant dose amounts to no more than 90% of the high dopant dose of the first subregions 1082 and to more than 110% of the medium dopant dose of the first emitter region 1081. For example, based on such design, steps in the dV/dt over current profile and possible snap-backs may be reduced and thus, the device 1 may exhibit a more constant dV/dt over current profile. As illustrated, the third subregions 10823 may adjoin both the first emitter region 1081 and the first subregions 10821. For example, the third subregions 10823 couple one or more or all of the first subregions 10821 to the first emitter region 1081

Still referring to FIG. 9, in an embodiment, the first subregions 10821 exhibit a stripe configuration of multiple spatially distributed stripes, wherein a lateral width of the stripes varies within the second emitter region 1082. For example, the third subregions (stripes) 10823 may exhibit a greater width than the first subregions (stripes) 10821. The comparatively narrow first subregions (stripes) 10821 can be configured to inject holes only at larger current levels, in accordance with an embodiment.

In accordance with the embodiment schematically and exemplarily illustrated in FIG. 10, which can be considered as a further variation of the embodiment schematically and exemplarily illustrated in FIG. 8, the first emitter region 1081 comprises one or more further subregions 10811 forming a portion of the first lateral total area (e.g. less than 30% or 50% or 70% of the first lateral total area) and exhibiting, with respect to said portion and the second conductivity type, an increased dopant dose, wherein the increased dopant dose amounts to more than 150% of the medium dopant dose. For example, as apparent from the zoomed-in section of the first emitter region 1081 shown in FIG. 10, the further subregions 10811 are configured as narrow stripes. For example, the width of the further subregions (stripes) 10811 of the first emitter region 1081 is less than 20% of the width of the first subregions (stripes) 10821 of the second emitter region 1082. Based on the further subregions 10811, the risk of filamentation during turn-off of an overcurrent (of, e.g., twice the nominal current) may be not significantly enhanced, as the further subregions (stripes) 10811 do not inject holes at such current level. However, in case of an even higher load current of, e.g., more than five times the nominal load current, the further subregions (stripes) 10811 start injecting holes and thereby reduce the risk of device destruction, in accordance with an embodiment.

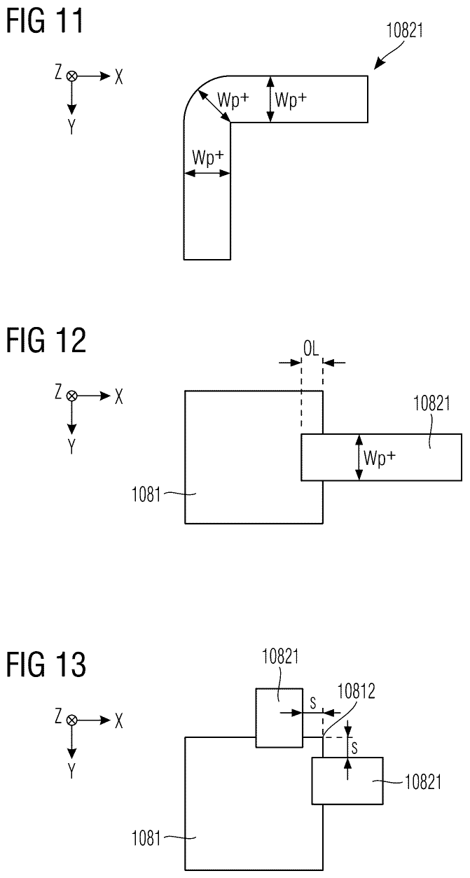

The features exemplarily and schematically illustrated in FIGS. 11 to 13 may be implemented in each of the herein described embodiments.

For example, referring to FIG. 11, the first subregions 10821 and/or the second subregions 10822 exhibit, in a top view on a horizontal cross-section, rounded edges. For example, the first subregions 10821 (having the high dopant dose) exhibit such rounded edge only at the peripheral side of the corner facing to the edge 1-4, whereas the inner side of the corner facing to the center of the active region 1-2 exhibits a sharp edge. Thus, regarding the meander configuration explained above, at a turn of the meander configuration, the width wₚ₊ of the first subregions (stripes) 10821 of the respective stripe may remain substantially constant.

Furthermore, referring to FIG. 12, each of said at least one of the one or more first subregions 10821 adjoining the first emitter region 1081 may have a lateral overlap OL with the first emitter region 1081 of at least 1 μm or of at least 5 μm.

Furthermore, referring to FIG. 13, said at least one of the one or more first subregions 10821 adjoining the first emitter region 1081 is arranged at a distance s to a corner 10812 of the first emitter region 1081, wherein said distance s amounts to at least 2 μm or to at least 10 μm.

In accordance with the embodiments schematically and exemplarily illustrated in FIGS. 14 and 15, the control terminal 13 comprises a gate pad 131 and, electrically connected thereto, gate fingers 133 and gate runners 132, which may extend as illustrated in these Figures. Also in accordance with the other embodiments described herein, the control terminal 13 may comprise said gate pad 131 and, electrically connected thereto, one or more gate fingers 133 and/or one or more gate runners 132.

Regarding the embodiment of FIG. 14, the first emitter region 1081 has a rectangular shape and is arranged in vicinity to the gate pad 131. Furthermore, one of the first subregions (stripes) 10821 is arranged at the transition from the active region 1-2 to the edge termination region 1-3, thereby surrounding the active region 1-2. Each of the first subregions (stripes) 10821 adjoin the first emitter region 1081. Furthermore, each of the first subregions (stripes) 10821 not surrounding the active region 1-2 may exhibit a similar length.

Regarding the embodiment of FIG. 15, the first subregions 10821 and the second subregions 10822 are arranged in parallel to each other and form a stripe pattern along the first lateral direction X. The first emitter region 1081 has a rectangular shape extending perpendicular to the stripe pattern and is arranged, e.g., in vicinity of one of the gate fingers 133. For example, the first emitter region's horizontal extension along the first lateral direction X (Δx) is substantially equal to the total lateral extension of the active region 1-2 along the first lateral direction. Again, each of the first subregions (stripes) 10821 adjoin the first emitter region 1081. Furthermore, one of the first subregions (stripes) 10821 is arranged at the right side of the transition from the active region 1-2 to the edge termination region 1-3, and another one of the first subregions (stripes) 10821 is arranged at the left side of the transition from the active region 1-2 to the edge termination region 1-3. Thereby, the active region 1-2 is surrounded by a portion of the first subregions (stripes) 10821 at least partially.

Presented herein is also a method of producing a power semiconductor device. For example, the method of producing a power semiconductor device comprises forming the following components in an active region: a semiconductor body comprising a drift region of a first conductivity type and exhibiting a front side and a back side opposite thereof; a first load terminal at the front side; a second load terminal at the back side; in the semiconductor body, a source region of the first conductivity type and a body region of a second conductivity type between the source region and the drift region, wherein both the source region and the body region are electrically connected to the first load terminal; in the semiconductor body, a back side emitter region of the second conductivity type electrically connected to the second load terminal between the drift region and the back side, wherein the back side emitter region is laterally segmented into at least a first emitter region and a second emitter region. The first emitter region has a first lateral total area and exhibits, with respect to said first lateral total area and the second conductivity type, a medium dopant dose. The second emitter region has a second lateral total area and comprises one or more first subregions and one or more second subregions, the first lateral total area amounting to less than 50% of the second lateral total area. The first subregions form a first portion of the second lateral total area and exhibit, with respect to said first portion and the second conductivity type, a high dopant dose, and the second subregions form a second portion of the second lateral total area and exhibit, with respect to said second portion and the second conductivity type, a low dopant dose. The high dopant dose amounts to more than 150% of the medium dopant dose, and the low dopant dose amounts to less than 50% of the medium dopant dose.

Embodiments of the above-described method correspond to the embodiments of the power semiconductor device 1 described above. Accordingly, these embodiments of the method will not literally be described herein, but it is referred to the above.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

What is claimed is:

1. A power semiconductor device, comprising:
a control terminal;
an active region with a semiconductor body comprising a drift region of a first conductivity type and having a front side and a back side opposite thereof;
a first load terminal at the front side;
a second load terminal at the back side;
in the semiconductor body, a source region of the first conductivity type and a body region of a second conductivity type between the source region and the drift region, wherein both the source region and the body region are electrically connected to the first load terminal;
in the semiconductor body, a back side emitter region of the second conductivity type electrically connected to the second load terminal between the drift region and the back side, wherein the back side emitter region is laterally segmented into at least a first emitter region and a second emitter region,
wherein the first emitter region has a first lateral total area and has, with respect to the first lateral total area and the second conductivity type, a medium dopant dose,
wherein the second emitter region has a second lateral total area and comprises one or more first subregions and one or more second subregions, the first lateral total area amounting to less than 50% of the second lateral total area,
wherein the one or more first subregions forms/form a first portion of the second lateral total area and has/have, with respect to the first portion and the second conductivity type, a high dopant dose,
wherein the one or more second subregions forms/form a second portion of the second lateral total area and has/have, with respect to the second portion and the second conductivity type, a low dopant dose,
wherein the high dopant dose amounts to more than 150% of the medium dopant dose,
wherein the low dopant dose amounts to less than 50% of the medium dopant dose.

2. The power semiconductor device of claim 1, wherein a lateral distance between the control terminal and the first emitter region is smaller compared to a second distance between the control terminal and the second emitter region.

3. The power semiconductor device of claim 1, wherein the first portion of the second lateral total area amounts to 50% to 150% of the second portion of the second lateral total area.

4. The power semiconductor device of claim 1, wherein the second emitter region has, based on the one or more first subregions and the one or more second subregions, a stripe configuration.

5. The power semiconductor device of claim 1, wherein the second emitter region has, based on the one or more first subregions and the one or more second subregions, a meander configuration.

6. The power semiconductor device of claim 1, wherein the one or more first subregions and/or the one or more second subregions has/have, in a top view on a horizontal cross-section, rounded edges.

7. The power semiconductor device of claim 1, wherein the one or more first subregions and the one or more second subregions are substantially evenly distributed within the second emitter region.

8. The power semiconductor device of claim 1, wherein the first emitter region has a contiguous configuration.

9. The power semiconductor device of claim 1, wherein the first emitter region has a lateral shape according to which a maximal total extension along a first lateral direction is within a range of 33% to 300% of a maximal total extension along any other lateral direction.

10. The power semiconductor device of claim 1, wherein the first emitter region comprises one or more further subregions having, with respect to the second portion and the second conductivity type, an increased dopant dose, and wherein the increased dopant dose amounts to more than 150% of the medium dopant dose.

11. The power semiconductor device of claim 1, wherein at least one of the one or more first subregions adjoins the first emitter region.

12. The power semiconductor device of claim 11, wherein the at least one of the one or more first subregions adjoining the first emitter region has a lateral overlap with the first emitter region of at least 1 μm.

13. The power semiconductor device of claim 11, wherein the at least one of the one or more first subregions adjoining the first emitter region is arranged at a distance to a corner of the first emitter region, and wherein the distance amounts to at least 2 μm.

14. The power semiconductor device of claim 1, wherein the second emitter region comprises one or more third subregions forming a third portion of the second lateral total area and having, with respect to the third portion and the second conductivity type, a medium-to-high dopant dose, wherein the medium-to-high dopant dose amounts to no more than 90% of the high dopant dose of the one or more first subregions and to more than 110% of the medium dopant dose of the first emitter region.

15. The power semiconductor device of claim 14, wherein the one or more third subregions adjoins/adjoin both the first emitter region and at least one or more of the one or more first subregions.

16. The power semiconductor device of claim 1, wherein the one or more first subregions has/have a stripe configuration of a plurality of spatially distributed stripes, and wherein a lateral width of the stripes varies within the second emitter region.

17. The power semiconductor device of claim 1, wherein both the one or more first subregions and the one or more second subregions have a stripe configuration of a plurality of spatially distributed stripes, and wherein a lateral width of the stripes of the one or more first subregions is substantially identical to a lateral width of the stripes of the one or more second subregions.

18. The power semiconductor device of claim 1, wherein portions of the source region and the body region laterally overlapping with the first emitter region and the second emitter region are equal.

19. The power semiconductor device of claim 1, wherein a first share of the source region and the body region laterally overlapping with the first emitter region and a second share of the source region and the body region laterally overlapping with the second emitter region are controlled based on a same voltage applied between the first control terminal and the control terminal.

20. The power semiconductor device of claim 19, wherein the first share has a first channel width, and the second share has a second channel width different from the first channel width.

21. The power semiconductor device of claim 19, wherein in the first share, the body region has a first body dopant dose, and wherein in the second share, the body region has a second body dopant dose different from the first body dopant dose.

22. The power semiconductor device of claim 19, wherein the first share and the second share are substantially equally configured.

23. The power semiconductor device of claim 1, wherein the power semiconductor device has an IGBT configuration or an RC IGBT configuration.

24. The power semiconductor device of claim 1, wherein the power semiconductor device has an edge termination region surrounding the active region, and wherein each of the drift region, the source region, the body region and the emitter region are arranged in the active region.

25. The power semiconductor device of claim 1, wherein each of one or more first subregions adjoins the first emitter region.

26. The power semiconductor device of claim 1, wherein the active region is at least partially surrounded by at least one of one or more of the one or more first subregions and one or more portions of the first emitter region.

27. A power semiconductor device having a vertical IGBT configuration or a vertical RC IGBT configuration, the power semiconductor device comprising, in an active region:
a back side emitter region laterally segmented into at least a first emitter region and a second emitter region,
wherein the first emitter region has a first lateral total area and, with respect to the first lateral total area and a second conductivity type, a medium dopant dose,
wherein the second emitter region has a second lateral total area and comprises one or more first subregions and one or more second subregions,
wherein the first lateral total area amounts to less than 50% of the second lateral total area,
wherein the one or more first subregions forms/form a first portion of the second lateral total area and has/have, with respect to the first portion and the second conductivity type, a high dopant dose,
wherein the one or more second subregions forms/form a second portion of the second lateral total area and has/have, with respect to the second portion and the second conductivity type, a low dopant dose,
wherein the high dopant dose amounts to more than 150% of the medium dopant dose,
wherein the low dopant dose amounts to less than 50% of the medium dopant dose.

28. A method of producing a power semiconductor device, the method comprising:
forming a semiconductor body comprising a drift region of a first conductivity type and having a front side and a back side opposite thereof;
forming a first load terminal at the front side;
forming a second load terminal at the back side;
forming, in the semiconductor body, a source region of the first conductivity type and a body region of a second conductivity type between the source region and the drift region, wherein both the source region and the body region are electrically connected to the first load terminal;
forming, in the semiconductor body, a back side emitter region of the second conductivity type electrically connected to the second load terminal between the drift region and the back side, wherein the back side emitter region is laterally segmented into at least a first emitter region and a second emitter region,
wherein the first emitter region has a first lateral total area and has, with respect to the first lateral total area and the second conductivity type, a medium dopant dose,
wherein the second emitter region has a second lateral total area and comprises one or more first subregions and one or more second subregions,
wherein the first lateral total area amounts to less than 50% of the second lateral total area,
wherein the one or more first subregions forms/form a first portion of the second lateral total area and has/have, with respect to the first portion and the second conductivity type, a high dopant dose,
wherein the one or more second subregions forms/form a second portion of the second lateral total area and has/have, with respect to the second portion and the second conductivity type, a low dopant dose,
wherein the high dopant dose amounts to more than 150% of the medium dopant dose, and
wherein the low dopant dose amounts to less than 50% of the medium dopant dose.
